(19) United States
(12) Patent Application Publication
(10) Pub. No.: US 2008/0179619 A1
(43) Pub. Date: Jul. 31, 2008

(54) Edge-emitting light-emitting diode

(75) Inventors: Ching-Huei Wu, San Chung City (TW); Ming-Shiun Wu, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/699,073

(22) Filed: Jan. 29, 2007

(51) Int. Cl. H01L 33/00

(52) U.S. Cl. 257/99; 257/E33.005

(57) ABSTRACT

An edge-emitting light-emitting diode comprises a base, a frame, and at least three chips. The base has a recessed cup on the front side. The frame is fixed on the recessed cup of the base. These chips are electrically connected to the frame inside the recessed cup. A depth between the upper edges of the chips and a top surface of the recessed cup is ranged from 0.3 mm to 3 mm. As a result, the edge-emitting light-emitting diode provides the function of light mixing and provides superior lighting effect.

### FIELD OF THE INVENTION

The present invention relates to an improved structure of edge-emitting light-emitting diode capable of mixing the light beams and increasing the lighting effect, and more particularly to an edge-emitting light-emitting diode applicable to a backlight module or the like.

### BACKGROUND OF THE INVENTION

It is well known that the initial light-emitting diode is formed by mounting a chip on a recessed part of a frame and performing the follow-up die bonding, wire bonding and molding steps so as to form a single piece of light-emitting diode. This single piece of light-emitting diode is generally applied to outdoor information displays, traffic lights, and brake lights on automobiles.

Recently, the light-emitting diode is gradually adopted as a light source for use in a backlight module. In this light-emitting diode, three primary colors of light are emitted from three primary color chips and then mixed so as to generate the mixed light for serving as a multi-colored light source. In order to improve the lighting effect, the light-emitting diode is designed to be a base, wherein a recessed cup is formed on the front side of the base. The chips are electrically connected to a frame, wherein the frame has several bended pins unidirectionally mounted on the lateral surface of the base. As a result, the light beams, which are emitted from the chips of the light-emitting diode, can be mixed, and then condensed by the recessed cup of the base for outward projection via the top surface of the base so as to enhance the lighting effect.

The conventional light-emitting diode of the backlight module is capable of improving the lighting effect. However, it is still unable to provide optimum lighting. As a result, there is still a need to improve this structure.

In view of the foregoing description, the motive of the present invention is to provide the general public with an improved structure of edge-emitting light-emitting diode.

### SUMMARY OF THE INVENTION

It is a main object of the present invention to provide an edge-emitting light-emitting diode capable of mixing the light beams and increasing the lighting effect for increasing the practicability.

In order to achieve the above-mentioned objects, an edge-emitting light-emitting diode comprises a base, a frame, and at least three chips. The base has a recessed cup on the front side. The frame is fixed on the recessed cup of the base. These chips are electrically connected to the frame inside the recessed cup. A depth between the upper edges of the chips and a top surface of the recessed cup is ranged from 0.3 mm to 3 mm. As a result, the edge-emitting light-emitting diode provides the function of light mixing and provides superior lighting effect.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational diagram of the present invention.

FIG. 2 is a cross-sectional view taken along line A-A of FIG. 1.

FIG. 3 is a cross-sectional view taken along line B-B of FIG. 1.

### DETAILED DESCRIPTION OF THE PREFERRED EMBODIMENT

The objects, features, advantages, and benefits of the invention will become apparent in the following description taken in conjunction with the foregoing drawings.

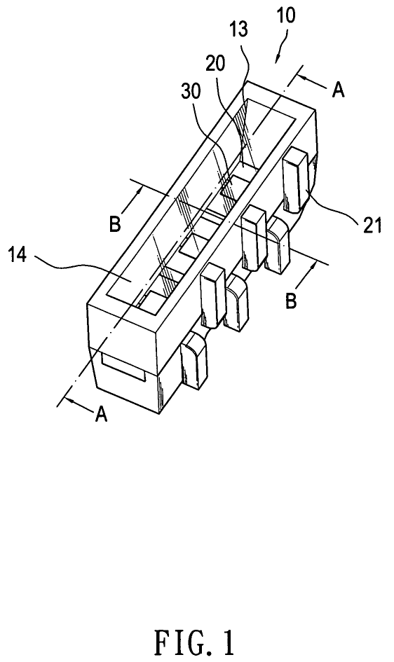

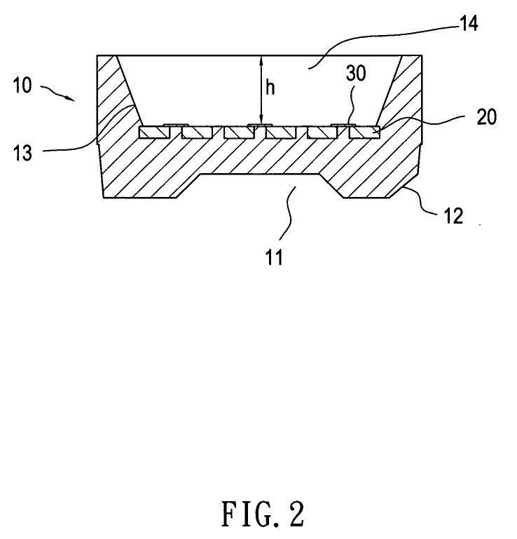

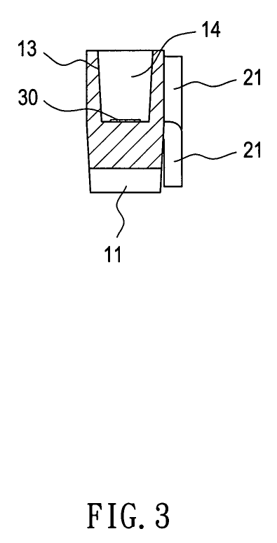

Referring to FIG. 1 through FIG. 3, an edge-emitting light-emitting diode of the present invention comprises a base 10, wherein a recessed part 11 is formed on the center portion of the bottom of the base 10. The base 10 has a bevel edge 12 on one side of the bottom. The base 10 has a recessed cup 13 on the top. The recessed cup 13 has angles of inclination on the front, back, left and right. A frame 20 is fixed on the inside of the recessed cup 13. At least three chips 30 are mounted on the frame 20 and electrically connected with the frame 20. In addition, a depth h between the upper edges of the chips 30 and the top surface of the recessed cup 13 is ranged from 0.3 mm to 3 mm. In addition, a gel 14 is filled into the recessed cup 13 for sealing the recessed cup 13.

In addition, several bended pins 21 are extended from one side of the frame 20, and these bended pins 21 are interlacedly, symmetrically arranged on the base 10 toward opposite directions.

In accordance with above-mentioned structure, when in use, the chips 30 mounted inside the recessed cup 13 of the base 10 can emit and mix the light beams so as to generate various colors of light. In addition, the depth h between the upper edges of the chips 30 and the top surface of the recessed cup 13 is ranged from 0.3 mm to 3 mm so that the light beams emitted from the chips 30 can be condensed by the recessed cup 13 and projected outward via the gel 14 so as to increase the lighting effect.

As described above, the recessed cup that has specific depth is formed in the base, and at least three chips are mounted inside the recessed cup so that the chips can emit and mix the light beams and the recessed cup can condense the light beams for increasing the lighting effect.

In summary, the present invention indeed achieves the expected objects by disclosing an edge-emitting light-emitting diode capable of increasing the lighting effect. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. An edge-emitting light-emitting diode comprising:
a base having a recessed cup on the front side thereof;
a frame fixed on the inside of said recessed cup of said base and having a plurality of pins extending therefrom and arranged on a lateral surface of said base; and
at least three chips electrically connected to said frame inside said recessed cup, a depth from upper edges of said chips to a top surface of said recessed cup being ranged from 0.3 mm to 3 mm; and
a gel filled into said recessed cup of said base for sealing said recessed cup.

2. An edge-emitting light-emitting diode of claim 1, wherein said pins extending from said frame are bended.

3. An edge-emitting light-emitting diode of claim 2, wherein said bended pins are arranged interlacedly, symmetrically on said lateral surface of said base toward opposite directions.
